(19) United States
(12) Patent Application Publication
(10) Pub. No.: US 2023/0262936 A1
(43) Pub. Date: Aug. 17, 2023

(54) MULTI-FUNCTION COVER FOR PRINTED CIRCUIT BOARD ASSEMBLY

(71) Applicant: Nebulon, Inc., Fremont, CA (US)

(72) Inventors: EUGENE YAN KI HSUE, San Ramon, CA (US); SAHBA ETAATI, Los Altos, CA (US)

(21) Appl. No.: 18/012,797

(22) PCT Filed: Jun. 22, 2021
(86) PCT No.: PCT/US2021/038483

§ 371 Date: Dec. 23, 2022

Related U.S. Application Data
(60) Provisional application No. 63/042,732, filed on Jun. 23, 2020.

(51) Int. Cl. H05K 7/20; H05K 1/02

(52) U.S. Cl. CPC H05K 7/2039; H05K 1/0203; H05K 7/20709

(57) ABSTRACT

A device such as an add-in card 100 for a computer system includes a circuit board assembly (110) and a cover (120). The cover (120) has two sides and a top extending between the sides. The sides contact a major surface of the circuit board assembly (110) adjacent to and along opposite edges. The cover (120) may protect electronic components of the circuit board assembly (110) and control air flows, flatness, and rigidity of a device. The cover (120) may further be sized and shaped to limit movement of electronic components of the circuit board assembly (110).

### BACKGROUND

Printed circuit assemblies must meet many mechanical and thermal requirements to provide robust electronic devices. For example, flexibility in long, thin printed circuit boards may be problematic because flexing of a circuit board can damage delicate features or dislodge electronic components on the circuit board. Additionally, flexibility in pluggable devices such as add-in server cards makes the pluggable devices prone to dislodge when subjected to dynamic forces. Warping is another mechanical problem for pluggable devices even when the board is rigid because a warped board may make prevent terminals on the circuit board assembly from properly meshing with a socket. Because of these issues, printed circuit assemblies often require additional mechanical elements to improve rigidity or flatness of the overall structure.

High-power electronic components in printed circuit assemblies can introduce additional thermal and mechanical issues. A large integrated circuit such as a microprocessor, for example, can generate concentrated heat that requires a heat spreader with relatively high surface area and mass to keep the integrated circuit from overheating. In addition to the weight burden a heat spreader places on the printed circuit board assembly, the geometry and density of fins on the heat spreaders in a printed circuit board assembly typically creates a highly directional flow impedance, and the heat spreaders operate most efficiently if air flows are directed along the gaps between fins. A printed circuit board assembly may thus require one or more baffles to direct airflow as needed to effectively cool high-power integrated circuits. The heat spreaders and baffles may also require high clamping forces that put enormous stress on the printed circuit boards, particularly if the heat spreaders are used (intentionally or otherwise) as handles for physical manipulation of the circuit board assemblies. A printed circuit board assembly may thus require reinforcement and flow control structures to survive handling and provide functional reliably.

### BRIEF DESCRIPTION OF THE DRAWINGS

FIG. 1 shows a perspective view of an add-in card in accordance with one example of the present disclosure.

FIG. 2 shows an exploded view of the add-in card of FIG. 1.

FIG. 3 shows a perspective view of a server system including host server hardware with an add-in card in accordance with one example of the present disclosure.

FIGS. 4-1 and 4-2 show top and side view of a server add-in card having air flows in accordance with an example of the present disclosure when just server fans are operating.

FIGS. 5-1 and 5-2 show top and side view of a server add-in card having air flows in accordance with an example of the present disclosure when just the blower in the add-in card is operating.

The drawings illustrate examples for the purpose of explanation and are not of the invention itself. Use of the same reference symbols in different figures indicates similar or identical items.

### DETAILED DESCRIPTION

In accordance with an aspect of the present disclosure, a removable cover for a circuit board assembly protects the assembly, acts as a structural exoskeleton, controls flatness of the assembly, secures critical components within the assembly, and functions as a duct or baffle to direct the flow of air within the assembly. In contrast, some prior systems may require separate covers, stiffeners, and baffles to address individual problems. A single multifunction cover as described herein may provide a space-efficient solution that incorporates the necessary features to address a combination of problems without negatively impacting cost, performance, or reliability of an assembled device.

In one specific example, a device such as a server add-in card includes a circuit board and a cover attached to the circuit board. The cover has a generally flattened U-shaped cross-section with two side and a top, the top extending between the sides. The two sides have edges that contact a major surface of the circuit board adjacent to and along opposite edges of the circuit board. The contact of the circuit board with the sides of the cover controls flatness and stiffness of the device along a length of the device in that the cover can limit bending, warping, and racking or twisting of the device along the width and height of the device. The circuit board and cover together create and air duct that extends along a length of the circuit board and has an open inlet at one end. The duct controls a primary direction of air flow through the device, and electronic components having heat sinks with fins may be oriented so that gaps between the fins extend along the primary air flow direction.

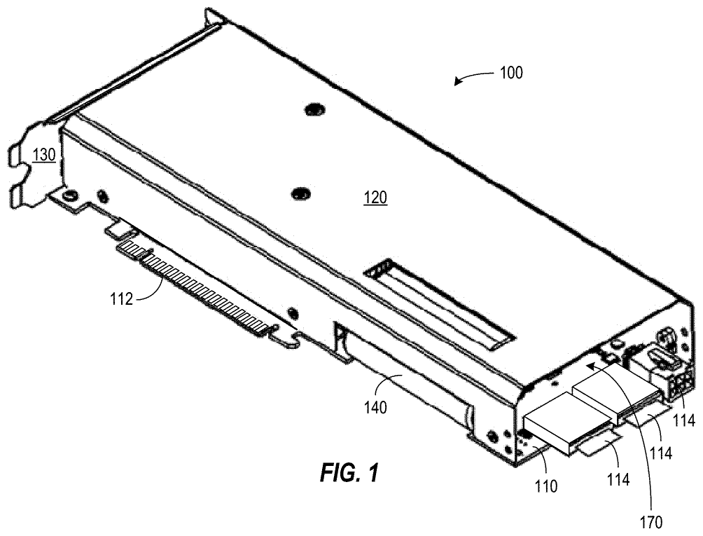

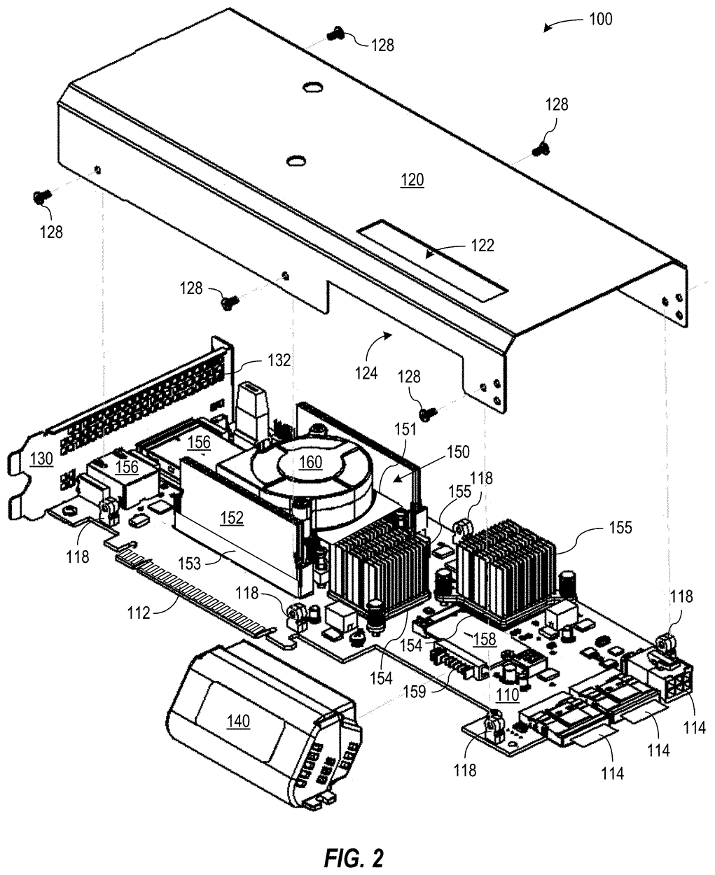

FIGS. 1 and 2 respectively show assembled and exploded views of one example of an add-in card 100 in accordance with one example of the present disclosure. The term “add-in card” is used herein in a general sense to refer to an electronic device that may be added to or used in different computer systems, and a common example of an add-in card includes a circuit board assembly with terminals that may be plugged into a slot or socket on an industry-standard bus in a host computer such as a host server. Add-in card 100 in the illustrated example is generally configured to be installed in a host server and may be compliant with one or more industry standards that computer systems use. For example, add-in card 100 may be compliant with Industry Standard Architecture (ISA), Extended Industry Standard Architecture (EISA), Micro Channel Architecture (MCA), Peripheral Component Interconnect (PCI), PCI Express (PCI-X), or Small Computer Systems Interface (SCSI) standards.

The primary elements of add-in card 100 include a circuit board assembly 110 and a cover 120. As used herein, “circuit board assembly” refers to a circuit board that may further include electronic or mechanical components. Circuit board assembly 110 particularly includes a printed circuit board with terminals 112 arranged to fit into a slot or socket in a host such as a server or other computer system in which add-in card may be installed. Terminals 112 may provide electrical power and signal connections between add-in card 100 and the host. Assembly 110 may further include auxiliary connectors 114, e.g., one or more signal interface connectors or auxiliary power connectors, that provide additional electrical power or signal connections of add-in card 100 to the host or other electronic systems. A panel 130 attached perpendicularly to one end of circuit board assembly 110 may engage mechanical features of the host server, so that panel 130 provides additional mechanical mounting that secures add-in card 100 with terminals 112 engaged in a socket for operation inside the host server.

Add-in card 100, in the illustrated example, further includes a backup power unit 140 that may plug into circuit board assembly 110 and be held in place by cover 120. One example of backup power unit 140 for add-in card 100 may include a battery, e.g., a rechargeable laptop battery. Associated charging and power control circuits may reside on circuit board assembly 110 or in backup power unit 140. In one example, charging and battery management circuitry is housed entirely in the battery module 140, and no battery circuitry is on the rest of circuit board assembly 110. Backup power unit 140 in one example of the present disclosure includes one or more rechargeable batteries, a charger for the battery or batteries, control circuitry that controls whether backup power unit 140 is being charge or is providing power, and a sensor that senses whether add in card 100 is receiving external power, e.g., from the host or from an auxiliary power line and/or receiving a cooling air flow. The charging circuits generally keep backup power unit 140 charged when the host server provides power to add-in card 100, and backup power unit 140 may provide backup power to assembly 110 when the host stops providing power to add-in card 100.

The exploded view of FIG. 2 further reveals active electronic components that are generally inside cover 120 when add-in card 100 is assembled as shown in FIG. 1. As shown in FIG. 2, circuit board assembly 110 includes electronic components 150, 152, 154, 156, and 158 that implement the functions of add-in card 100. In the illustrated example, assembly 110 more particularly includes a main processor 150 with associate memory 152, e.g., DIMM modules, one or more co-processors 154, a solid-state drive or non-volatile storage unit 158, and other integrated circuits and electronic components 156 such as interface circuits, non-volatile memory, voltage converters, clock circuits, resistors, capacitors, and inductors that may be mounted in sockets or soldered of circuit board assembly 110. In the illustrated example, circuit board assembly 110 includes a socket 159 for backup power unit 140, so that backup power unit 140 may easily be removed and replaced.

In general, electronic components 150, 152, 154, 156, and 158 consume electrical power and generate waste heat. Some components 150 and 154, e.g., processor or controller integrated circuits, are integrated circuits that generate significant heat in compact areas and have associated heat sinks or spreaders 151 and 155 on the integrated circuits to pull away heat. Heat sinks or spreaders 151 and 155 may have fins or other cooling structures to disperse the heat through conduction, radiation, or convection. Heat sinks or spreaders 151 or 155 generally have channels or gaps for air flows through their fins or other cooling structures. As described further below, main processor 150, in the implementation shown in FIG. 2, has a blower 160 on the heat sink 151 of main processor 150. Alternatively, other types of air circulators such as fans could be employed. Operation of blower 160 draws or helps create air flows through the heat sink or spreader 151 of main processor 150, and drawing air up through heat sink or spreader 151 can cause or help cause air flows along the surfaces of circuit board assembly 110 and the electronic or thermal components 152, 154, 155, 156, and 158 mounted of circuit board assembly 110.

In accordance with a further aspect of the present disclosure, removable cover 120 of add-in card 100 performs multiple functions. Cover 120 for printed circuit board assembly 110 secures and protects critical components (e.g., electronic components 150, 152, 154, 156, and 158 of circuit board assembly 110), acts as a structural exoskeleton to provide mechanical stiffness to add-in card 100, controls and improves the flatness of circuit board assembly 110, and functions as a baffle or a portion of a conduit or duct to direct the air flow within add-in card 110. The shape and length of cover 120 may particularly work in conjunction with on-board blower 160, placement of components 150, 152, 154, 156, and 158 and panel vents 132 to direct the air flow within add-in card 100 in a controlled and predictable manner, regardless of variable host environments for which add-in card 100 is intended to operate.

Cover 120 may be made using a metal sheet cut and bent to a length, width, and height required for add-in card 100 and having openings or features that accommodate attachment to circuit board assembly 110 and provide space for components of add-in card 100. A metal such as an aluminum alloy or galvanized steel generally has superior impact resistance when compared to other materials of the same thickness and therefore can protect fragile components such as heat sinks or spreaders and integrated circuits of circuit board assembly 110. Metal sheeting is also a relatively rigid material, and cover 120 has four bends, extending along its length, which in conjunction with the thickness of the material of cover 120, creates superior stiffness to limit bending along the length of add-in card 120 and to limit racking or twisting along the width and height of add-in card 100. In illustrated example, cover 120 has a generally flattened U-shaped cross-section with two flat sides that are parallel to each other and extend about the same length as circuit board assembly. A top of cover 120 may be flat and perpendicular to the sides, and each transition between a side and the top includes two acute angle bends, e.g., 45° bends, instead of a single 90° bend. The terms side and top are used here to indicate relative orientation, and in general, add-in card 100 may be installed with different orientations, e.g., vertical or horizontal, so that a side, the top, or the circuit board may be the highest or lowest part of the device 100 during use. In one example configuration, cover 120 is about 4 inches wide, about 1.3 inches tall, and about 10.5 inches long when circuit board assembly 110 has a width of about 4 inches and a length of about 10.5 inches.

The sides of cover 120 may be further cut or shaped to have two straight, e.g., sheared, edges that act as straightedges for support of printed circuit board assembly 110. A straight edge support may be important to ensure that the circuit board is straight and flat (not warped) so that terminals 112 may be easily aligned with and inserted into a socket in a host device. Holding flatness also protects the integrity of solder joints and signal integrity of the electrical signals running through traces in printed circuit board assembly 110. Rigidity that cover 120 provides may also be important to prevent flexing that could damage the circuit board or other components of assembly 110. In one example of the present disclosure, printed circuit board assembly 110 has posts 118 affixed to the circuit board for attachment of cover 120 using fasteners 128, e.g., screws or bolts, and posts 118 reside inside cover 120 and slightly offset from the nearest edge of circuit board assembly 110. Post 118 being affixed inside cover 120 may thus place edges of cover 120 in direct contact with a primary surface of the circuit board along substantially the entire length of printed circuit board assembly 110. The contact of the edges of cover 120 along the length of printed circuit board 110 controls the flatness of add-in card 100 to a high degree. In one configuration, posts 118 have threaded openings extending parallel to the surface of the circuit board to accept fasteners 128 and hold cover 120 and printed circuit board 110 together.

As shown in the example of FIGS. 1 and 2, cover 120 includes openings 122 and 124, e.g., two rectangular cutouts, respectively on the top or side of cover 120. The positions, sizes, and shapes of openings 122 and 124 may be chosen to provide space for backup power unit 140 and help to secure backup power unit 140 to assembly 110 by limiting the movement or displacement of backup power unit 140 while cover 120 is installed on the printed circuit board.

In accordance with a further aspect of the present disclosure, cover 120 may have a height selected to act as a secondary constraint that prevents one or more of components 150, 152, 154, 156, and 158 from unintentionally dislodging from sockets on circuit board assembly 110. In particular, memory 152 may include DIMM modules plugged into associated sockets on circuit board assembly 110, and the height of cover 120 may be about the same as the height that the DIMM modules 152 (or other tallest electronic components) extend above the circuit board when plugged into their sockets 153. The limited height of cover 120 may not provide room for removal of the plugged-in modules, so that cover 120 may thus prevent the modules form dislodging from their sockets on printed circuit board assembly 110 while cover 120 is attached to circuit board assembly 110. Similarly, portions of cover 120 are adjacent to or contact backup power unit 140 and constrain movement of backup power unit 140 to prevent backup power unit 140 from unplugging from its socket 159 on circuit board assembly 110 while cover 120 is attached to circuit board assembly 110. Constraint of backup power unit 140 may be critical because backup power unit 140 may include batteries that are relatively heavy, making backup power unit 140 easily dislodged during movement of add-in card 100. Cover 120 may additionally contact or otherwise limit the freedom of movement of other electronic components on circuit board assembly 110.

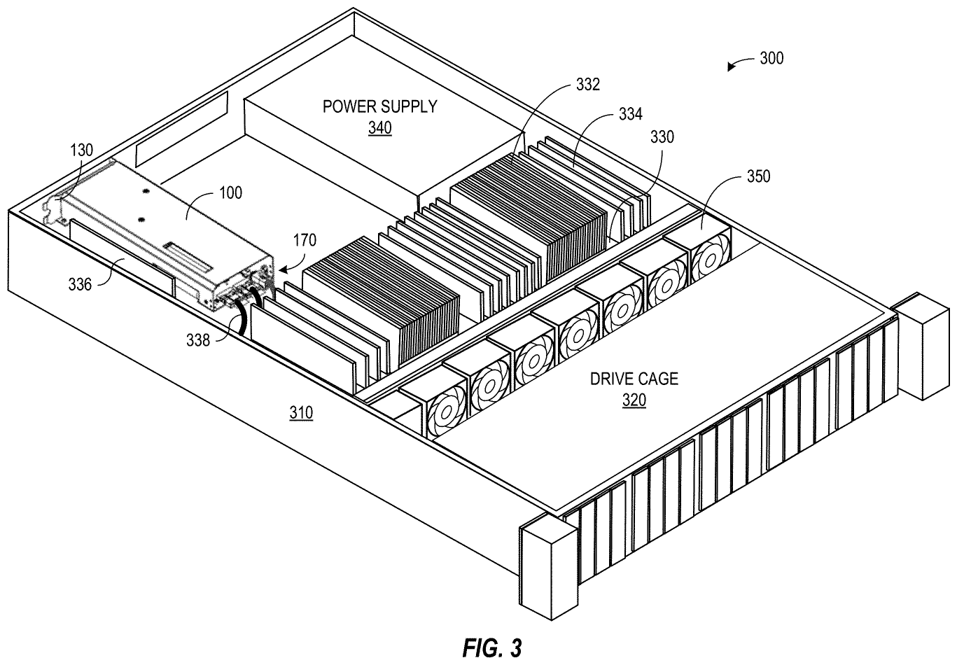

Another function of cover 120 is to define a conduit or duct for air flow through add-in card 100, when add-in card 100 is installed in a host. FIG. 3, for example, shows a perspective view of a host server 300 in accordance with one example of the present disclosure. Server 300 includes a chassis 310 containing conventional server systems 320, 330, 340, and 350 and one or more an add-in card 100 such as described above. Chassis 310 may be sized and shaped for mounting in a standard rackmount or pedestal server chassis (not shown). In an example of a typical rackmount server, chassis enclosure 310 may contain a drive cage 320 containing one or more removable storage devices such as hard disk drives, a motherboard 330 with one or more processors 332 and memory such as DIMM modules 334, a power subsystem 340 that provides power to the other server systems and to add-in cards/devices such as add-in card 100, and one or more air circulators such as cooling fans 350. Add-in card 100 alone or with other add-in devices may be installed in server system 300 by plugging terminals 112 of device 100 or 340 into respective sockets in server system 300, e.g., on a riser 336 extending from motherboard 330, and/or connecting cables 338 between each device 100 and sever systems 320. Cable 338 may, for example, connect between motherboard 330 and auxiliary connector 114 on add-in card 100.

Server 300, as noted above, has one or more cooling fans 350. Cooling fans 350 may be desired to pull an airflow through some server systems 320 from one face, e.g., the front, of chassis 310 and push the air flow back through other server systems, e.g., push air through the heat spreaders of processors 332 on server motherboard 330. Cooling fans 350 also push an air flow through add-in device(s) 100. In accordance with an aspect of the present disclosure, cover 120 and circuit board assembly 110 of add-in card 100 forms a duct or conduit with an open end 170 acting as an inlet of the duct defined by cover 120 and circuit board assembly 110 in add-in card 100. Inlet 170 and openings 122 and 124 in cover 120 of add-in card 100 receive air flows from fans 350, and the duct defined by cover 120 and circuit board assembly 110 directs the air flows through add-in card 100 and out of an outlet provided by panel vents 132 in panel 130 of add-in card 100.

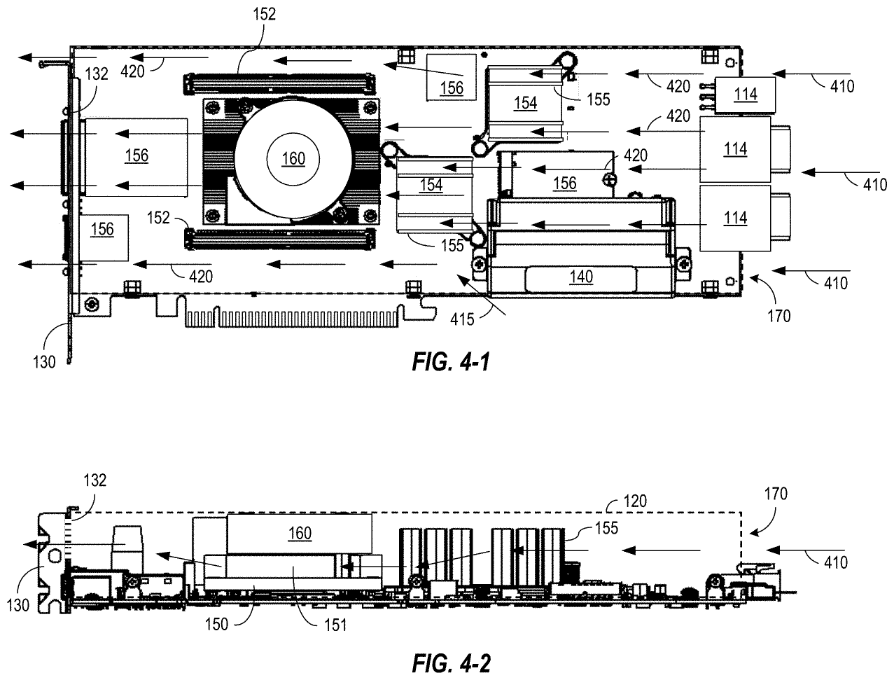

FIGS. 4-1 and 4-2 show top and side views of add-in card 100 with air flows in accordance with an example in which just the fans in the host server are operating. (Memory modules 152 are not shown in FIG. 4-2 and only a dashed outline of cover 120 is shown in FIGS. 4-1 and 4-2 to better illustrate the air flows.) As shown in FIGS. 4-1 and 4-2, air flows 410 and 415 from the server fans enter add-in device 100. Air flows 410 enter through inlet 170 at one end of add-in card 100. Other air flows 415 from the server fans may enter through side or top openings, e.g., openings 122 and 124 in cover 120 shown in FIG. 2. The duct defined by circuit board assembly 110 and cover 120 channels entering air flows 410 and 415 through add-in card 100 as air flows 420, which are generally along a length axis or direction of add-in card 100. For example, flows 420 generally pass along the duct formed by circuit board assembly 110 and cover 120, passing along components 150, 152, 154, and 156 and passing through heat sinks or spreaders 151 and 155, before exiting add-in card 100 through an outlet provided by panel vents 132 in panel 130. For efficient cooling, heat sinks or spreaders 151 and 155 of circuit board assembly 110 are ideally oriented so that gaps between fins of heat sinks or spreaders 151 and 155 extend along the air flow direction 420.

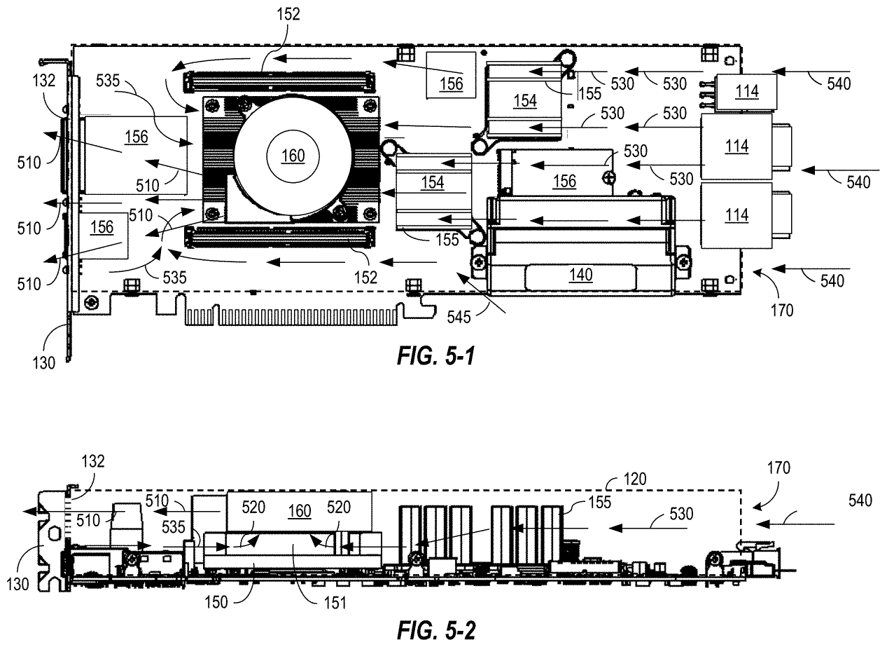

FIGS. 5-1 and 5-2 show top and side views of add-in card 100 with air flows in accordance with an example in which just blower 160 in add-in card 100 operates for cooling. (Again, memory modules 152 are not shown in FIG. 5-2 and only a dashed outline of cover 120 is shown in FIGS. 5-1 and 5-2 to better illustrate the air flows.) As shown in FIGS. 5-1 and 5-2, blower 160 is atop heat sink or spreader 151 of main processor 150 and pushes an air flow 510 out of add-in card 100 through the outlet provided by panel vents 132. Blower 160 also draws air 520 up through heat sink or spreader 151. As a result, air flows 530 on the server side, i.e., on the inlet side of the air duct, of blower 160 are generally pulled along the duct formed by circuit board assembly 110 and cover 120 in the same manner or directions as air flows (e.g., flows 420) that the server fans would push through add-in card 100. Accordingly, air flows 530 flow through heat sinks or spreaders 155 located on the inlet side from blower 160, along the gaps between the fins of heat sinks or spreaders 155 in the same manner as air flows 420 from server fans. Air flows 535 on into heat sink or spreader 151 from the lower regions on the panel side, i.e., the outlet side, of add-in card 100 are generally opposite to the direction of air flows 420 that the sever fans would push through add-in card 100 and opposite to the flows 510 that blower 160 pushes out of the outlet provided by panel vents 132.

In accordance with an important aspect of the present disclosure, air flows 540 and 545 drawn into add-in card 100 from inside the server chassis are in the same directions that the server fans would push air flows 410 and 415 into add-in card 100. Accordingly, blower 160 may be operated at the same time as the server fans and provide a superposition of the flows shown in FIGS. 4-1 and 5-1 inside add-in card 100, but the combined flows into add-in card 100 are in substantially the same directions as the inflows pushed by server fans alone. Blower 160 may thus be operated at the same time as the server fans to assist or improve air flows without significantly changing the cooling operations in the rest of the host server.

Blower 160 as noted above is inside the duct that circuit board assembly 110 and cover 120 form. Blower 160 is used as the air circulator in this particular example because a blower can draw air in one direction, e.g., an inflow direction that is generally upward, and direct out flowing air flow in an outflow direction generally perpendicular to the inflow direction. This allows air flows into blower 260 to be most concentrated in the heat sink or spreader 151 of the main processor 150. The most forced convection cooling may thus occur where the most heat generation is expected, e.g., by main processor 150. Additionally, a relatively large area, e.g., a diameter of about 40 mm, of blower 160 can be accommodated in the relatively restricted height, e.g., about 10 mm, between the circuit board and the top of cover 120. Other air circulators could alternatively be employed in an add-in device such as add-in device 100. For example, an electric fan may be placed anywhere along the length of the duct to pull air into inlet 170 of add-in device 100 and push air out of the outlet provided by panel vents 132. The diameter of a fan that provides incoming and outgoing air flows along the same axis may be limited to the height of the duct space between circuit board assembly 110 and the top plate of cover 120.

Although particular implementations have been disclosed herein, these implementations are only examples and should not be taken as limitations. Various adaptations and combinations of features of the implementations disclosed are within the scope of the following claims.

What is claimed is:

1. A device comprising:
a circuit board; and
a cover attached to the circuit board, the cover having a first side, a second side, and a top, the top extending between the first and second sides, the first side contacting a major surface of the circuit board adjacent to and along a first edge of the circuit board, the second side contacting the major surface of the circuit board adjacent to and along a second edge of the circuit board, the first edge being opposite to the second edge.

2. The device of claim 1, wherein the circuit board and the cover form an air duct having an inlet at a first end of the device and defining air flow direction along a length of the circuit board.

3. The device of claim 2, further comprising;
an electronic component mounted on the circuit board; and
a heat spreader mounted on the electronic component and having fins extending into the duct, the fins being separated by gaps extending along the air flow direction.

4. The device of claim 2, further comprising a panel at a second end of the device, the panel including one or more openings creating an outlet of the duct.

5. The device of claim 2, wherein each of the sides of the cover has an edge that is straight and contacts the major surface of the circuit board, contact of the edges of the cover and the circuit board controlling flatness of the circuit board and stiffness along the length of the device.

6. The device of claim 2, further comprising:
a socket on the circuit board; and
an electronic component plugged into the socket, a distance between the top of the cover and the socket being insufficient to permit removal of the electronic component from the socket.

7. The device of claim 1, further comprising:
a plurality of posts affixed to the circuit board adjacent to the first and second edges of the circuit board; and
fasteners attaching the cover to the posts with the first and second sides of the cover contacting the circuit board outside the posts.

8. The device of claim 7, wherein each of the sides of the cover has an edge that is straight and contacts the major surface of the circuit board, contact of the circuit board with the edges of the cover controlling flatness of the circuit board and stiffness along a length of the device.

9. The device of claim 1, wherein the cover comprises a metal sheet that forms the first side, the second side, and the top, the metal sheet including first and second bends between the first side and the top and including third and fourth bends between the second side and the top.

10. The device of claim 9, further comprising an electronic component attached to the circuit board, the metal sheet including one or more cutout shaped and positioned to accommodate and secure the electronic component within the device.

11. The device of claim 10, wherein the electronic component comprises a battery unit.

12. The device of claim 1, wherein each of the sides of the cover has an edge that is straight and contacts the major surface of the circuit board, contact of the circuit board with the edges of the cover controlling flatness of the circuit board and stiffness along a length of the device.

13. The device of claim 1, further comprising:
a socket on the circuit board; and
an electronic component plugged into the socket, a distance between the cover and the socket being insufficient to permit removal of the electronic component from the socket while the cover is attached to the circuit board.

14. The device of claim 13, wherein the electronic component comprises one of a memory module and a battery unit.
